(19) United States
(12) Patent Application Publication
(10) Pub. No.: US 2025/0095694 A1
(43) Pub. Date: Mar. 20, 2025

(54) MEMORY DEVICE AND METHOD OF MANUFACTURING THE SAME

(71) Applicant: SK hynix Inc., Icheon-si Gyeonggi-do (KR)

(72) Inventor: Jin Ha KIM, Icheon-si Gyeonggi-do (KR)

(73) Assignee: SK hynix Inc., Icheon-si Gyeonggi-do (KR)

(21) Appl. No.: 18/952,621

(22) Filed: Nov. 19, 2024

Related U.S. Application Data
(63) Continuation-in-part of application No. 17/552,944, filed on Dec. 16, 2021.

(30) Foreign Application Priority Data
Jul. 30, 2021 (KR) 10-2021-0100874

(51) Int. Cl. G11C 5/06; G11C 16/04; H10B 43/10; H10B 43/27

(52) U.S. Cl. CPC G11C 5/063; G11C 16/0483; H10B 43/10; H10B 43/27

(57) ABSTRACT

A memory device, and a method of manufacturing the same, includes interlayer insulation layers spaced apart from each other and stacked, gate lines formed between the interlayer insulation layers, and a plug vertically passing through the interlayer insulation layers and the gate lines. Each of the gate lines includes a barrier layer formed along an inner wall of the interlayer insulation layer and the plug, a first conductive layer surrounded by the barrier layer, and a second conductive layer surrounded by the first conductive layer and having a grain size different from a grain size of the first conductive layer. A volume of the second conductive layer is variable along a direction in which the gate lines extend.

### CROSS-REFERENCE TO RELATED APPLICATION

The present application is a Continuation in Part of U.S. patent application Ser. No. 17/552,944 filed on Dec. 16, 2021 which claims priority to Korean patent application number 10-2021-0100874 filed on Jul. 30, 2021, in the Korean Intellectual Property Office, the entire contents of which applications are incorporated herein by reference.

### BACKGROUND

### 1. Field of Invention

The present disclosure relates to a memory device and a method of manufacturing the same, and more particularly, to a memory device capable of reducing a resistance of word lines included in the memory device, and a method of manufacturing the same.

### 2. Description of Related Art

A memory device may be classified as a volatile memory device for which stored data is lost when supplied power is interrupted or a non-volatile memory device for which stored data is maintained even when supplied power is interrupted.

A non-volatile memory device may include NAND flash memory, NOR flash memory, resistive random access memory (ReRAM), phase-change random access memory (PRAM), magnetoresistive random access memory (MRAM), ferroelectric random access memory (FRAM), spin transfer torque random access memory (STT-RAM), or the like.

Memory cells included in the NAND flash memory may be connected between word lines and bit lines, and may be programmed or read according to a voltage applied to the word lines and the bit lines. As an integration degree of the memory device increases, a side of the word lines decreases, and thus the difficulty of manufacturing the memory device increases.

### SUMMARY

An embodiment of the present disclosure provides a memory device and a method of manufacturing the same for preventing a void, an air gap, or a seam from being formed in word lines during a manufacturing process of the memory device.

According to an embodiment of the present disclosure, a memory device includes interlayer insulation layers spaced apart from each other and stacked, gate lines formed between the interlayer insulation layers, and a plug vertically passing through the interlayer insulation layers and the gate lines. Each of the gate lines includes a barrier layer formed along an inner wall of the interlayer insulation layer and the plug, a first conductive layer surrounded by the barrier layer, and a second conductive layer surrounded by the first conductive layer and having a grain size different from a grain size of the first conductive layer. A volume of the second conductive layer is variable along a direction in which the gate lines extend.

According to an embodiment of the present disclosure, a memory device includes interlayer insulation layers and gate lines alternately stacked on each other between bit lines and source lines, plugs vertically passing through the interlayer insulation layers and the gate lines, and a first slit vertically passing through the interlayer insulation layers and the gate lines to the interlayer insulation layers and the gate lines into different memory blocks. Each of the gate lines includes a barrier layer, a first conductive layer surrounded by the barrier layer, and a second conductive layer surrounded by the first conductive layer and having a grain size different from a grain size of the first conductive layer. A size of the second conductive layer increases with decreasing distance of the second conductive layer from the first slit.

According to an embodiment of the present disclosure, a method of manufacturing a memory device includes alternately stacking interlayer insulation layers and sacrificial layers, forming plugs vertically passing through the interlayer insulation layers and the sacrificial layers, forming a slit vertically passing through the interlayer insulation layers and the sacrificial layers in a boundary area between different memory blocks, removing the sacrificial layers exposed through a sidewall of the slit, forming a first conductive layer in an area from which the sacrificial layers are removed, and filling a void generated when the first conductive layer is formed with a second conductive layer having a first grain size different from a grain size of the first conductive layer.

According to an embodiment of present disclosure, a void, an air gap, or a seam may be prevented from being formed in word lines, and a resistance of the word lines may be reduced. Therefore, reliability of the display device may be improved.

### BRIEF DESCRIPTION OF THE DRAWINGS

FIG. 1 is a block diagram illustrating a memory device according to an embodiment of the present disclosure.

FIG. 2 is a circuit diagram illustrating an embodiment of a memory cell array shown in FIG. 1.

FIG. 3 is a cross-sectional view illustrating a memory device according to an embodiment of the present disclosure.

FIGS. 4A to 4L are diagrams illustrating a method of manufacturing a memory device according to an embodiment of the present disclosure.

FIG. 5 is a plan view illustrating a memory device according to an embodiment of the present disclosure.

FIG. 6 is a cross-sectional view illustrating a memory device according to another embodiment of the present disclosure.

FIG. 7 is a plan view illustrating a memory device according to another embodiment of the present disclosure.

FIG. 8 is a cross-sectional view illustrating a memory device according to another embodiment of the present disclosure.

FIG. 9 is a plan view illustrating a memory device according to another embodiment of the present disclosure.

FIG. 10 is a cross-sectional view illustrating a memory device according to another embodiment of the present disclosure.

FIG. 11 is a plan view illustrating a memory device according to another embodiment of the present disclosure.

FIG. 12 is a cross-sectional view illustrating a memory device according to another embodiment of the present disclosure.

FIG. 13 is a diagram illustrating a solid state drive (SSD) system to which a memory device of the present disclosure is applied.

FIG. 14 is a diagram illustrating a memory card system to which a memory device of the present disclosure is applied.

### DETAILED DESCRIPTION

Specific structural or functional descriptions of embodiments disclosed in the present specification or application are illustrated to describe the concept of the present disclosure. Embodiments according to the concept of the present disclosure may be carried out in various forms and should not be construed as being limited to the presented embodiments.

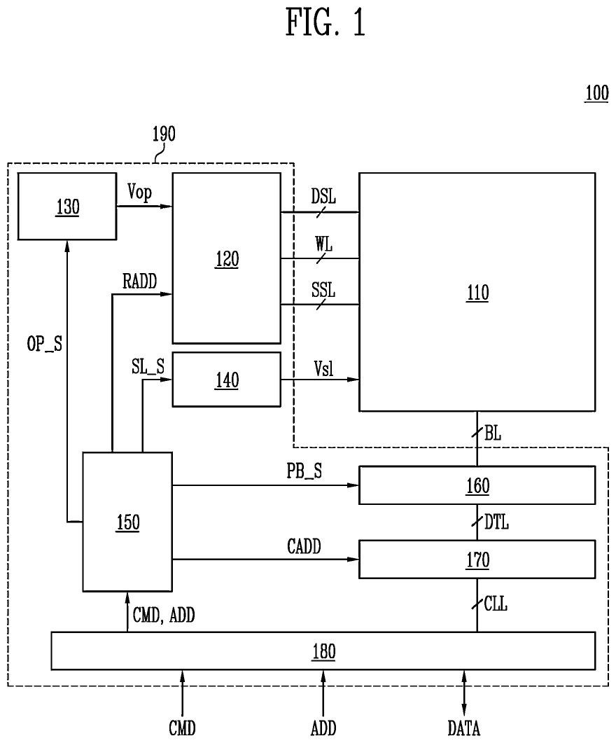

FIG. 1 is a block diagram illustrating a memory device according to an embodiment of the present disclosure.

Referring to FIG. 1, the memory device 100 may include a peripheral circuit 190 and a memory cell array 110.

The peripheral circuit 190 may be configured to perform a program operation and a verify operation for storing data in the memory cell array 110, a read operation for outputting data stored in the memory cell array 110, or an erase operation for erasing data stored in the memory cell array 110. The peripheral circuit 190 may include a voltage generating circuit 130, a row decoder 120, a source line driver 140, a control circuit 150, a page buffer 160, a column decoder 170, and an input-output circuit 180.

The memory cell array 110 may include a plurality of memory cells in which data is stored. In an embodiment, the memory cell array 110 may be a three-dimensional memory cell array. The plurality of memory cells may store single bit or multi bit data of two or more bits according to a program method. The plurality of memory cells may configure a plurality of memory cell strings. Each memory cell string may include a plurality of memory cells connected in series to each other through a channel structure. The channel structure may be connected to the page buffer 160 through a plurality of bit lines BL.

The voltage generating circuit 130 may generate various operation voltages Vop used for the program operation, the verify operation, the read operation, or the erase operation in response to an operation signal OP_S. For example, the voltage generating circuit 130 may selectively generate and output the operation voltages Vop including a program voltage, a verify voltage, a pass voltage, a read voltage, and an erase voltage.

The row decoder 120 may be connected to the memory cell array 110 through a plurality of drain select lines DSL, a plurality of word lines WL, and a plurality of source select lines SSL. The row decoder 120 may transmit the operation voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transmitted to a source line connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit line BL. The page buffer 160 may temporarily store data DATA received through the plurality of bit lines BL in response to the page buffer control signal PB_S. The page buffer 160 may sense a voltage or a current of the plurality of bit lines BL during the read operation.

The column decoder 170 may transmit the data DATA input from the input-output circuit 180 to the page buffer 160 in response to the column address CADD, or transmit the data DATA stored in the page buffer 160 to the input-output circuit 180. The column decoder 170 may transmit and receive the data DATA to and from the input-output circuit 180 through column lines CLL, and may transmit and receive the data DATA to and from the page buffer 160 through data lines DTL.

The input-output circuit 180 may transmit the command CMD and the address ADD received from an external device (for example, a controller) connected to the memory device 100 to the control circuit 150, and output the data received from the column decoder 170 to the external device.

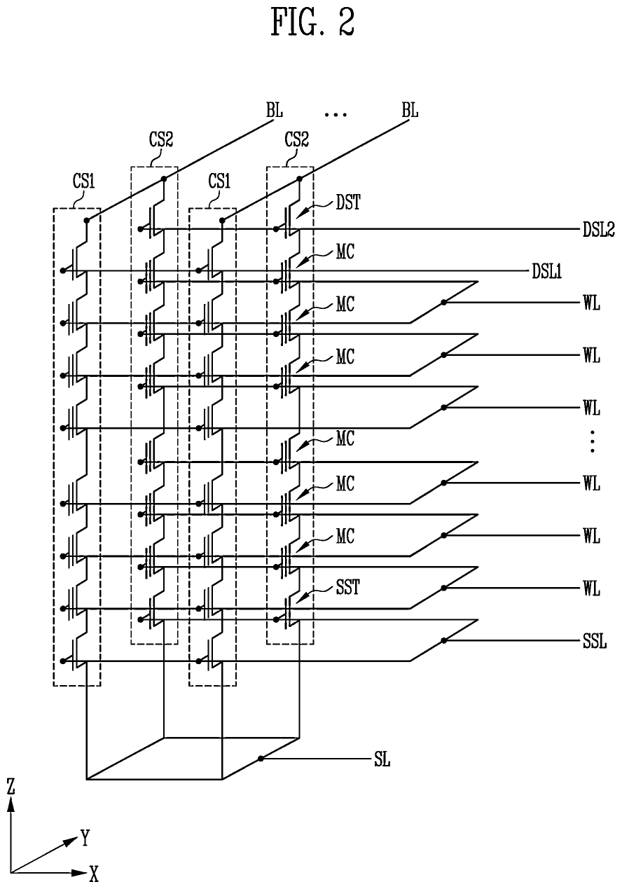

FIG. 2 is a circuit diagram illustrating an embodiment of the memory cell array shown in FIG. 1.

Referring to FIG. 2, the memory cell array may include first and second memory cell strings CS1 and CS2 connected to the plurality of bit lines BL. The first and second memory cell strings CS1 and CS2 may be commonly connected to the source line SL. That is, the first and second memory cell strings CS1 and CS2 may be connected between the bit lines BL and the source line SL. At least a pair of the first memory cell string CS1 and the second memory cell string CS2 may be connected to each of the bit lines BL.

The first memory cell string CS1 and the second memory cell string CS2 may include a source select transistor SST, a plurality of memory cells MC, and a drain select transistor DST disposed between the source line SL and the bit line BL. The first and second memory cell strings CS1 and CS2 may be arranged to be spaced apart from each other in first and second directions (X and Y directions), and may extend in a third direction (Z direction). For example, the first and second directions (X and Y directions) may be directions parallel to a substrate, and the third direction (Z direction) may be a direction perpendicular to the substrate. The first, second, and third directions (X, Y, and Z directions) may be perpendicular to each other.

The source select transistors SST may control an electrical connection between the plurality of memory cells MC and the source line SL. Although the figure shows that one source select transistor SST is included in one memory cell string, two or more source select transistors connected in series may be included in one memory cell string. Gates of the source select transistors SST may be connected to the source select line SSL. The source select transistors SST may be turned on or turned off according to a voltage applied to the source select line SSL.

The plurality of memory cells MC may be connected between the source select transistor SST and the drain select transistor DST. The plurality of memory cells MC between the source select transistor SST and the drain select transistor DST may be connected in series to each other. Gates of the plurality of memory cells MC may be connected to the plurality of word lines WL, respectively. The memory cells MC may be programmed or read by a voltage applied to the word lines WL. A group of memory cells MC connected to the same word line WL may become a page, and the program or read operation may be performed in a page unit.

The drain select transistors DST may control an electrical connection between the plurality of memory cells MC and the bit lines BL. Gates of the drain select transistors DST may be connected to a drain select line DSL1 or DSL2. The drain select transistors DST may be turned on or turned off according to a voltage applied to the drain select line DSL1 or DSL2. For example, the first memory cell strings CS1 may be connected to the first drain select line DSL1, and the second memory cell strings CS2 may be connected to the second drain select line DSL2. Therefore, during the program or read operation, memory cell strings connected to a drain select line selected from the first and second drain select lines DSL1 and DSL2 may be selected. For example, when the first drain select line DSL1 is selected, the first memory cell strings CS1 connected to the first drain select line DSL1 may be selected.

The source select line SSL, the word lines WL, and the drain select lines DSL1 and DSL2 may extend in the first direction (X direction), and may be spaced apart from each other and stacked in the third direction (Z direction). The bit lines BL may extend in the second direction (Y direction) and may be spaced apart from each other in the first direction (X direction).

Although not shown in the drawing, the source select line SSL may also be separated like the drain select lines DSL1 and DSL2 and connected to the first and second memory cell string CS1 or CS2, respectively.

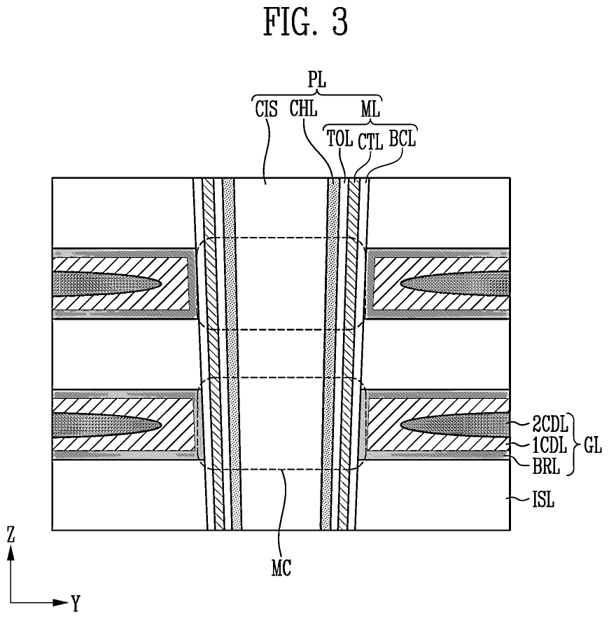

FIG. 3 is a cross-sectional view illustrating a memory device according to an embodiment of the present disclosure.

Referring to FIG. 3, the memory device may include a memory block in which data is stored, and the memory block may include a plurality of memory cells MC stacked on each other. The plurality of memory cells MC may be included in a plug PL that vertically passes through gate lines GL stacked on each other. A portion of the gate lines GL may be used as a word line and another portion may be used as a select line.

First interlayer insulation layers 1ISL may be formed between the gate lines GL. Therefore, the plug PL may be formed to vertically pass through the first interlayer insulation layers 1ISL and the gate lines GL. The first interlayer insulation layers 1ISL may be formed of an oxide layer or a silicon oxide layer. Each of the gate lines GL may include a barrier layer BRL, a first conductive layer 1CDL, and a second conductive layer 2CDL. The barrier layer BRL may be formed to prevent diffusion of an impurity between the gate lines GL and the first interlayer insulation layers 1ISL and between the gate lines GL and the plug PL. Therefore, the barrier layer BRL may be formed to surround the first conductive layer 1CDL. The barrier layer BRL may be formed of titanium nitride (TIN).

The first conductive layer 1CDL may be formed in an area surrounded by the barrier layer BRL, and the second conductive layer 2CDL may be formed in an area surrounded by the first conductive layer 1CDL. In other words, the second conductive layer 2CDL may be filled in an empty space formed in the first conductive layer 1CDL. In the present embodiment, because the second conductive layer 2CDL is formed to fill a void, an air gap, or a seam that may be generated in the first conductive layer 1CDL during a manufacturing process of the memory device, a size of the second conductive layer 2CDL may be different according to an area of the memory block, and an area where the second conductive layer 2CDL is not formed may exist.

The second conductive layer 2CDL may be formed of a material having physical properties different from physical properties of the first conductive layer 1CDL. For example, the first conductive layer 1CDL may be formed of tungsten (W), and the second conductive layer 2CDL may be formed of molybdenum (Mo).

The plug PL may include a memory layer ML and a core insulation layer CIS. The memory layer ML may be formed in a cylindrical shape passing through the first interlayer insulation layers 1ISL and the gate lines GL in the third direction (Z direction). The memory layer ML may include a blocking layer BCL, a charge trap layer CTL, and a tunnel insulation layer TOL. The blocking layer BCL may be formed in a cylindrical shape passing through the first interlayer insulation layers 1ISL and the gate lines GL in the vertical direction (Z direction), and may be formed of an insulation material. For example, the blocking layer BCL may be formed of an oxide layer. The charge trap layer CTL may be formed in a cylindrical shape along an inner wall of the blocking layer BCL, and may be formed of a material capable of storing a negative charge during the program operation. For example, the charge trap layer CTL may be formed of a nitride layer. The tunnel insulation layer TOL may be formed in a cylindrical shape along an inner wall of the charge trap layer CTL. The tunnel insulation layer TOL may be formed of an insulation material, for example, an oxide layer. A channel layer CHL may be formed in a cylindrical shape along an inner wall of the tunnel insulation layer TOL, and a voltage may be applied through the bit line or the source line. For example, the channel layer CHL may be formed of a polysilicon layer. The core insulation layer CIS may be formed along an inner wall of the channel layer CHL or may be formed to fill the entire inner area. For example, the core insulation layer CIS may be formed in a cylindrical shape in an inner area of the channel layer CHL. The core insulation layer CIS may be formed of an insulation material, for example, an oxide layer.

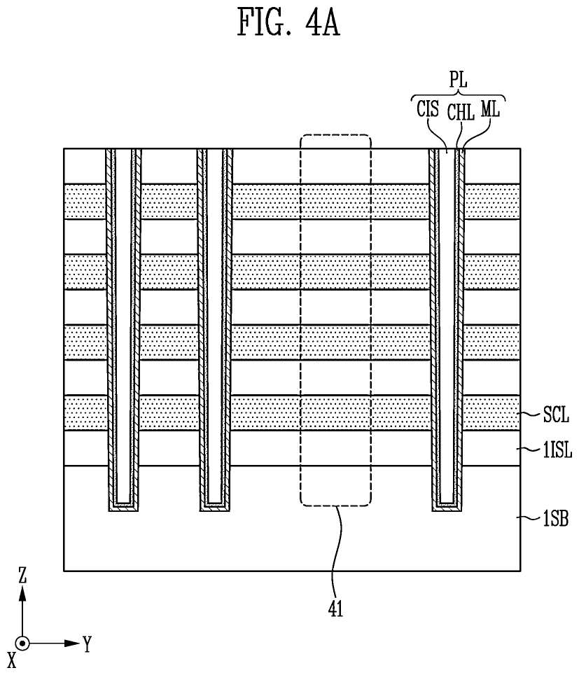

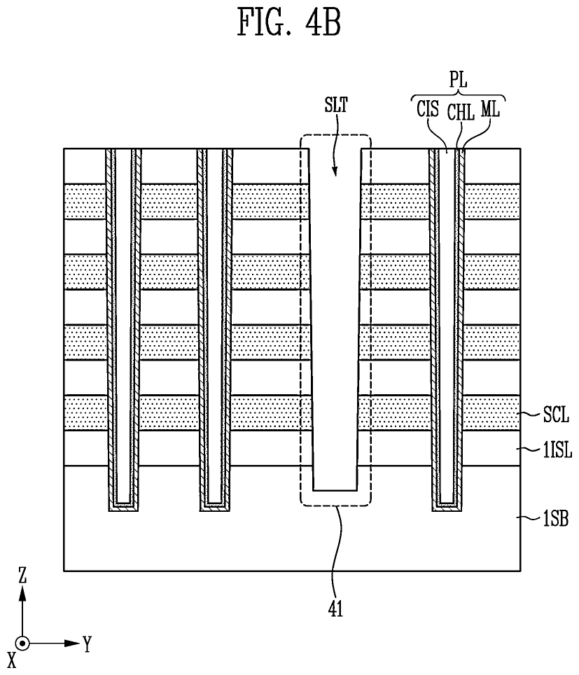

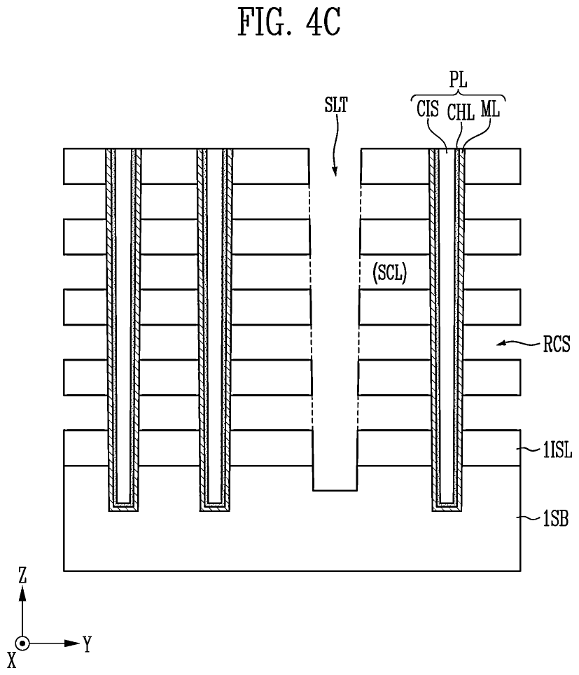

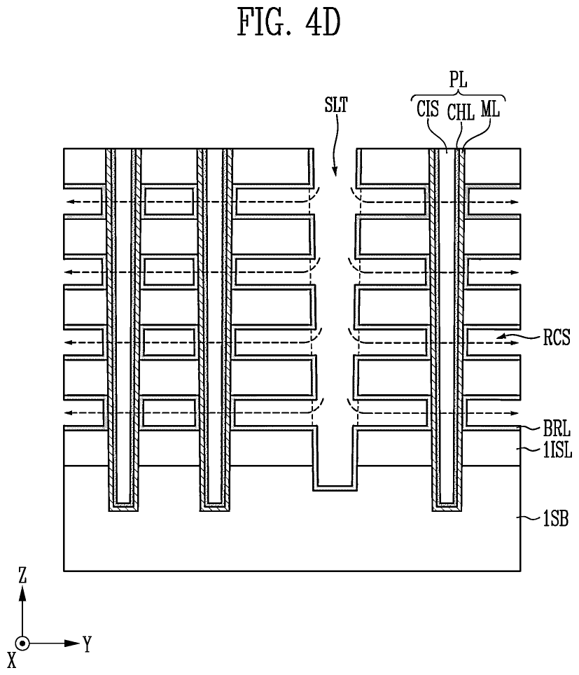

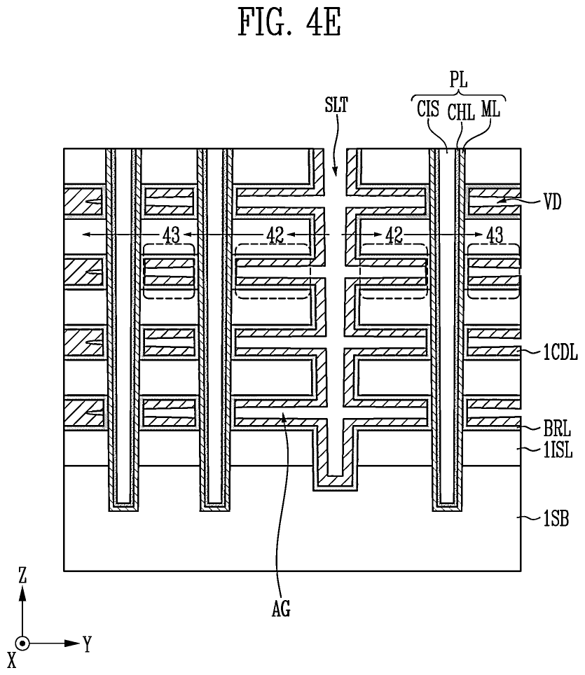

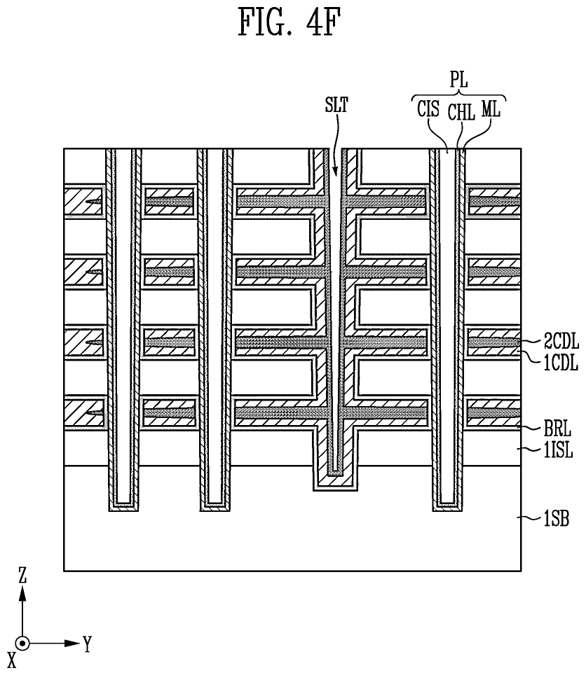

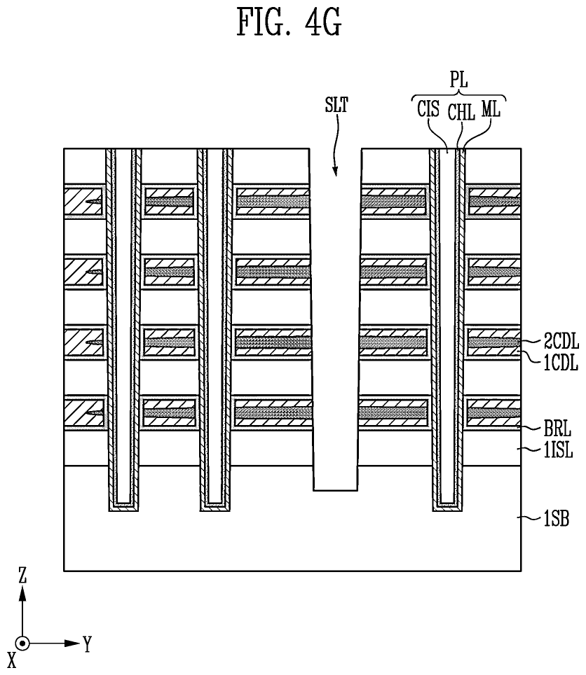

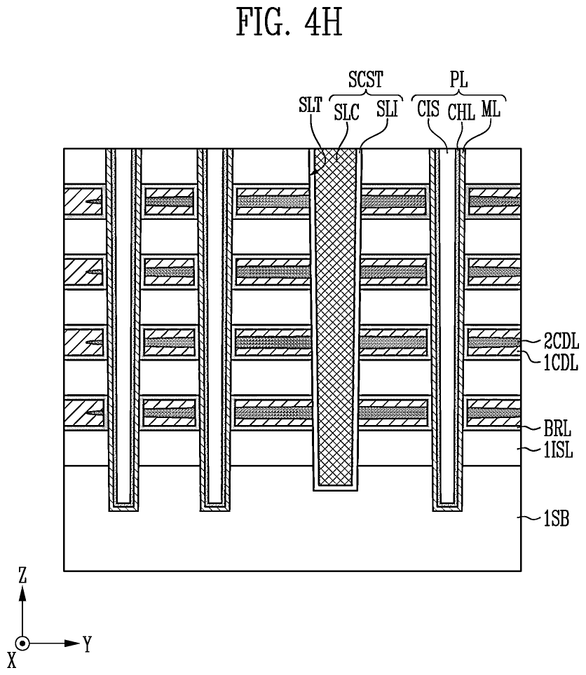

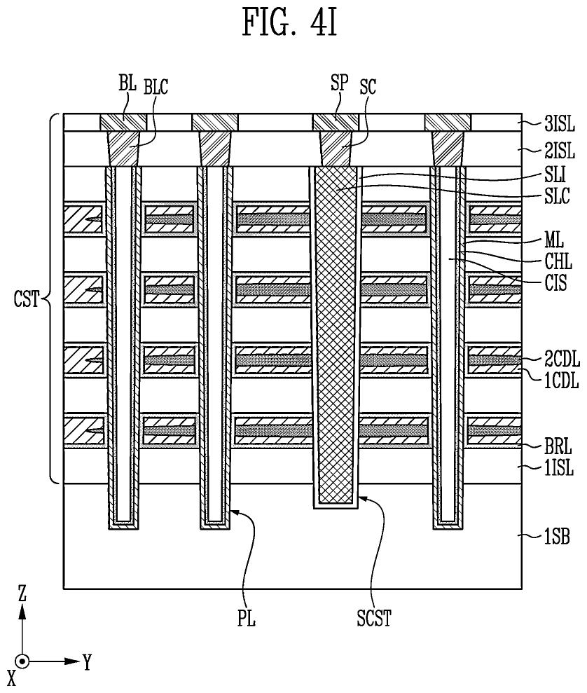

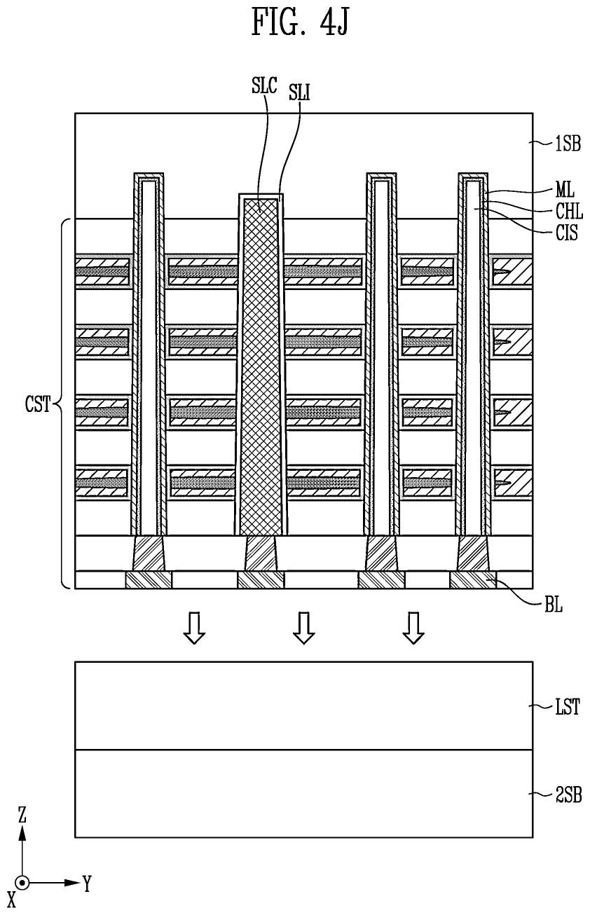

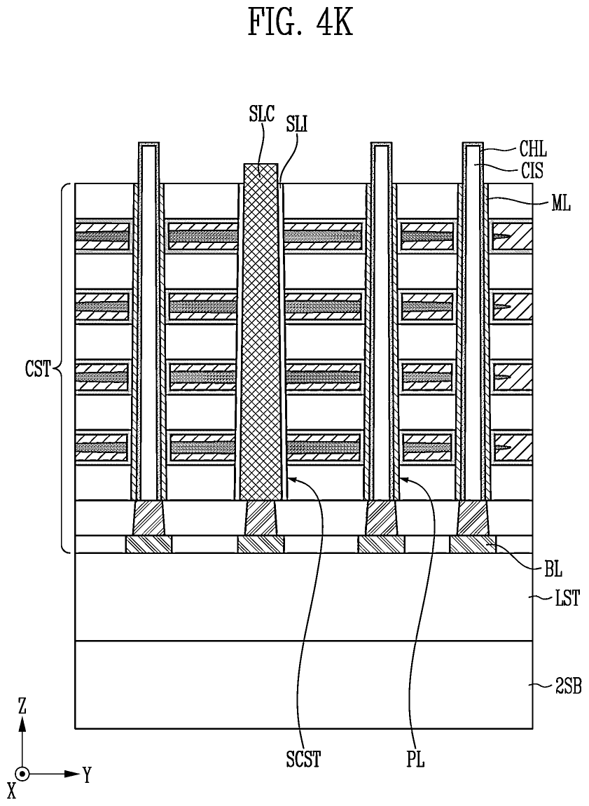

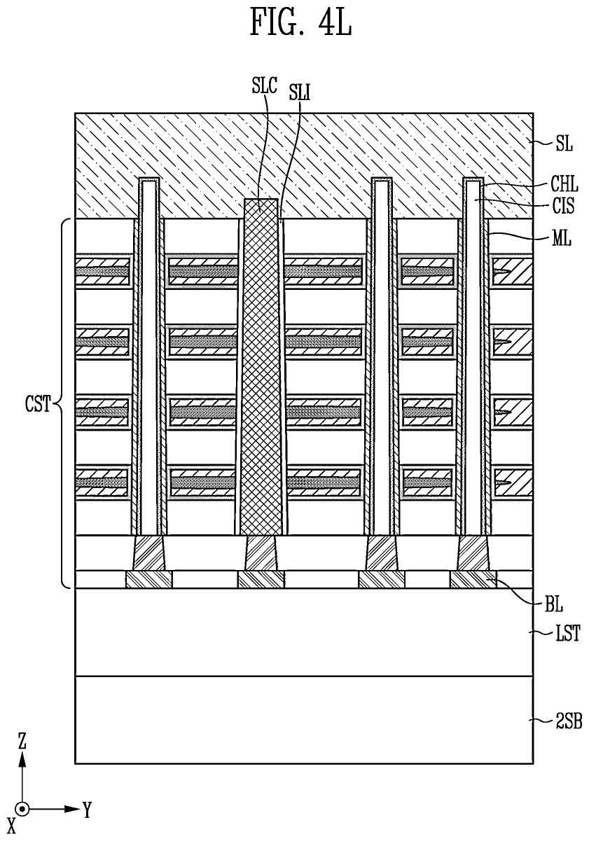

FIGS. 4A to 4L are diagrams illustrating a method of manufacturing a memory device according to an embodiment of the present disclosure.

Referring to FIG. 4A, the first interlayer insulation layers 1ISL and the sacrificial layers SCL may be alternately stacked on a first substrate 1SB, and the plugs PL vertically passing though the first interlayer insulation layers 1ISL and the sacrificial layers SCL may be formed. The plugs PL may extend into the first substrate 1SB.

The first interlayer insulation layers 1ISL may be formed of a silicon oxide layer, and the sacrificial layers SCL may be formed of a silicon nitride layer.

Each of the plugs PL may include the memory layer ML, the channel layer CHL, and the core insulation layer CIS. The memory layer ML may include the blocking layer BCL, the charge trap layer CTL, and the tunnel insulation layer TOL, as described with reference to FIG. 3. The plugs PL may be spaced apart from each other at a predetermined distance, and are not formed in a slit area 41 for dividing the memory blocks. For example, the plugs PL may extend in the third direction (Z direction) to the first substrate 1SB and may be disposed to be spaced apart from each other along the first and second directions (X and Y directions).

Referring to FIG. 4B, in order to form a slit SLT in the slit area 41, a step of etching a portion of the first interlayer insulation layers 1ISL and the sacrificial layers SCL stacked on the slit area 41 may be performed. An etching process for forming the slit SLT may be performed by a dry etching process. The etching process may be performed until a portion of the first substrate 1SB exposed through the slit SLT is etched. Because the slit SLT is formed to vertically pass through the first interlayer insulation layers 1ISL and the sacrificial layers SCL, the first interlayer insulation layers 1ISL, the sacrificial layers SCL, and the first substrate 1SB may be exposed through a sidewall of the slit SLT.

Referring to FIG. 4C, an etching process for removing the sacrificial layers SCL exposed through an inside of the slit SLT may be performed. The etching process may be performed by a wet etching process so that the sacrificial layers SCL formed between the first interlayer insulation layers 1ISL and the plugs PL may be removed. As an etchant used in the etching process, an etchant having a higher selectivity for the sacrificial layers SCL than the first interlayer insulation layers 1ISL, the plugs PL, and the first substrate 1SB may be used.

Because the etchant is supplied through the slit SLT, the sacrificial layers SCL close to the slit SLT may be etched among the sacrificial layers SCL. When the etching process is performed, because the sacrificial layers SCL between the first interlayer insulation layers 1ISL are removed, a recess which is an empty space may be formed between the interlayer insulation layers ISL.

Referring to FIG. 4D, the barrier layer BRL may be formed along a surface of the entire structure exposed by removing the sacrificial layers. The barrier layer BRL may be formed to prevent diffusion of an impurity between the gate line GL and the plug PL and between the gate line GL to be formed in a subsequent process and the interlayer insulation layer ISL. A source gas for forming the barrier layer BRL may be supplied through the slit SLT. Therefore, the barrier layer BRL may be formed along a surface of the entire structure exposed through the slit SLT and the recess RCS. The barrier layer BRL may be formed of titanium nitride (TIN).

Referring to FIG. 4E, the first conductive layer 1CDL may be formed along a surface of the entire structure in which the barrier layer BRL is formed. The first conductive layer 1CDL may be formed of tungsten (W) or molybdenum (Mo). A conductive layer is required to fill a space between the first interlayer insulation layers 1ISL, but as a distance between the first interlayer insulation layers 1ISL decreases, a void, an air gap, or a seam may be formed in some areas between the first interlayer insulation layers 1ISL. Accordingly, in the present embodiment, in order to prevent occurrence of the void, the air gap, or the seam between the first interlayer insulation layers 1ISL, the first conductive layer 1CDL and a second conductive layer 2CDL of FIG. 4F are sequentially formed between the first interlayer insulation layers 1ISL. For example, after forming the first conductive layer 1CDL having a void VD between the first interlayer insulation layers 1ISL, the void VD may be filled with the second conductive layer 2CDL. A method of forming the first conductive layer 1CDL is described with reference to FIG. 4E as follows.

Because the source gas for forming the first conductive layer 1CDL is supplied through the slit SLT, the first conductive layer 1CDL may be filled from an area farther from the slit SLT. Therefore, the void VD formed in an area 42 close to the slit SLT is larger than the void VD formed in an area 43 relatively far from the slit SLT. That is, a size of the void VD formed between the first conductive layer 1CDL may be increased as the void VD is close to the slit SLT and may be decreased as the void VD is far from the slit SLT. In addition, the size of the void VD may vary according to a space, a distance, or a thickness between the first interlayer insulation layers 1ISL.

The first conductive layer 1CDL may be formed along an inner wall of the barrier layer BRL, but may be formed so that the close area 42 is not blocked in a state in which the void VD is formed in the area 43 far from the slit SLT. In other words, the first conductive layer 1CDL may be formed along the inner wall of the barrier layer BRL, and a process of forming the first conductive layer 1CDL may be stopped in a state in which all voids VD formed between the first conductive layers 1CDL are connected.

Referring to FIG. 4F, the second conductive layer 2CDL may be formed in the void VD between the first conductive layers 1CDL. The second conductive layer 2CDL may be a conductive layer formed of a material having physical properties different from physical properties of the first conductive layer 1CDL. For example, the second conductive layer 2CDL may be formed of a material having a melting point different from that of the first conductive layer 1CDL. For example, the second conductive layer 2CDL may be formed of molybdenum (Mo) or tungsten (W). When the first conductive layer 1CDL is formed of tungsten (W), the second conductive layer 2CDL is formed of molybdenum (Mo). When the first conductive layer 1CDL is formed of molybdenum (Mo), the second conductive layer 2CDL is formed of tungsten (W).

Because an atomic mass of molybdenum (Mo) is less than that of tungsten (W), and a melting point of molybdenum (Mo) is lower than that of tungsten (W), a diffusion coefficient of an atom of molybdenum (Mo) is greater than that of tungsten (W). Because a diffusion coefficient of a material is increased, movement of an atom is active in a crystallization step, a grain size of molybdenum (Mo) is greater than that of tungsten (W). Because a movement speed of an electron in a material is decreased at a grain boundary, resistance may be decreased as a grain size of the material increases. After the second conductive layer 2CDL is formed, a heat treatment process may be further performed. When the heat treatment process is performed, as the first and second conductive layers 1CDL and 2CDL are recrystallized, a boundary between an interface may be decreased. For example, as a conductive layer formed of molybdenum (Mo) among the first and second conductive layers 1CDL and 2CDL are recrystallized, a gap that may occur between the first and second conductive layers 1CDL and 2CDL may be filled. Therefore, the void, the air gap, or the seam may be removed between the first and second conductive layers 1CDL and 2CDL. Because the gap that may occur between the first and second conductive layers 1CDL and 2CDL is removed, chemical penetration that may occur in a subsequent process may be prevented.

The second conductive layer 2CDL may be formed along an inner wall of the first conductive layer 1CDL. The second conductive layer 2CDL may be formed so that all voids VD are filled between the first interlayer insulation layers 1ISL1, but may be formed so that all slits SLT are filled or only a portion of the slits SLT are filled, in an area where the slits SLT is formed.

Referring to FIG. 4G, an etching process for removing the barrier layer BRL, the first conductive layer 1CDL, and the second conductive layer 2CDL formed in the slit SLT may be performed. The etching process may be performed by a dry etching process. When the barrier layer BRL, the first conductive layer 1CDL, and the second conductive layer 2CDL inside the slit SLT are removed by the etching process, the interlayer insulation layer ISL, the barrier layer BRL, the first conductive layer 1CDL, and the second conductive layer 2CDL may be exposed through a sidewall of the slit SLT.

Referring to FIG. 4H, a slit isolation layer SLI and a source line contact SLC may be formed in the slit SLT. The slit isolation layer SLI may be formed of a silicon oxide layer. The source line contact SLC may be formed of a conductive material. For example, the source line contact SLC may be formed of a polysilicon layer. The slit isolation layer SLI and the source line contact SLC formed in the slit SLT may become a source contact structure SCST.

Referring to FIG. 4I, a second interlayer insulation layer 2ISL, bit line contacts BLC, and a source contact SC may be formed on the source contact structure SCST, the plugs PL, and the first interlayer insulation layer 1ISL. The second interlayer insulation layer 2ISL may be formed of a silicon oxide layer. The bit line contacts BLC and the source contact SC may be formed of a conductive material. The bit line contacts BLC may be formed on the plugs PL. For example, the bit line contacts BLC may electrically contact the channel layers CHL of the plugs PL. The source contact SC may be formed on the source contact structure SCST. The second interlayer insulation layer 2ISL may be formed between the bit line contacts BLC and the source contact SC. A third interlayer insulation layer 3ISL, bit lines BL, and a source pad SP may be formed on the second interlayer insulation layer 2ISL, the bit line contacts BLC, and the source contact SC. The third interlayer insulation layer 3ISL may be formed of a silicon oxide layer. The bit lines BL and the source pad SP may be formed of a conductive material. The bit lines BL may be formed on the bit line contacts BLC, and the source pad SP may be formed on the source contact SC. The third interlayer insulation layer 3ISL may be formed between the bit lines BL and the source pad SP.

Accordingly, a cell structure CST including the bit lines BL, the source pad SP, the plugs PL, the source contact structure SCST, the barrier layer BRL, the first conductive layer 1CDL, and the second conductive layer 2CDL may be formed.

Referring to FIG. 4J, a lower structure LST may be formed on a second substrate 2SB. The lower structure LST may include the peripheral circuit 190 shown in FIG. 1. Using a wafer bonding technique, the flipped cell structure CST contacts the lower structure LST. Although not shown in the drawing, additional bonding pads may be formed at a portion where the cell structure CST and the lower structure LST contact each other.

Referring to FIG. 4K, an etching process for removing the first substrate 1SB of FIG. 4J positioned on the cell structure CST may be performed. The etching process may be performed as a wet etching process, but is not limited thereto. When the first substrate 1SB is removed, an upper portion of the plugs PL and the source contact structure SCST may be exposed. An etching process for removing the memory layer ML of the exposed plugs PL and for removing the slit isolation layer SLI of the exposed source contact structure SCST may be performed. As the etching process, a dry etching process or a wet etching process may be performed. As described with reference to FIG. 3, because the memory layer ML includes the blocking layer BCL, the charge trap layer CTL, and the tunnel insulation layer TOL, the blocking layer BCL, the charge trap layer CTL, and the tunnel insulation layer TOL may be sequentially removed by changing the etching gas or etchant during the etching process. Because the slit isolation layer SLI may be formed of the same material as the blocking layer BCL or the tunnel insulation layer TOL, the slit isolation layer SLI may be removed simultaneously when the blocking layer BCL or the tunnel insulation layer TOL is removed. When the memory layer ML and the slit isolation layer SLI protruding above the cell structure CST are removed, the channel layer CHL and the source line contact SLT protruding above the cell structure CST are exposed.

Referring to FIG. 4L, a source line SL may be formed on the cell structure CST. The source line SL may be formed of a conductive material. For example, the source line SL may be formed of polysilicon. The source line SL may contact the source line contact SLT and the channel layer CHL in which the cell structure CST protrudes upwardly. After forming the source line SL, an ion injection process injecting an impurity may be further performed to lower a resistance of the source line SL. For example, during the ion injection process, an N-type impurity may be injected into the source line SL.

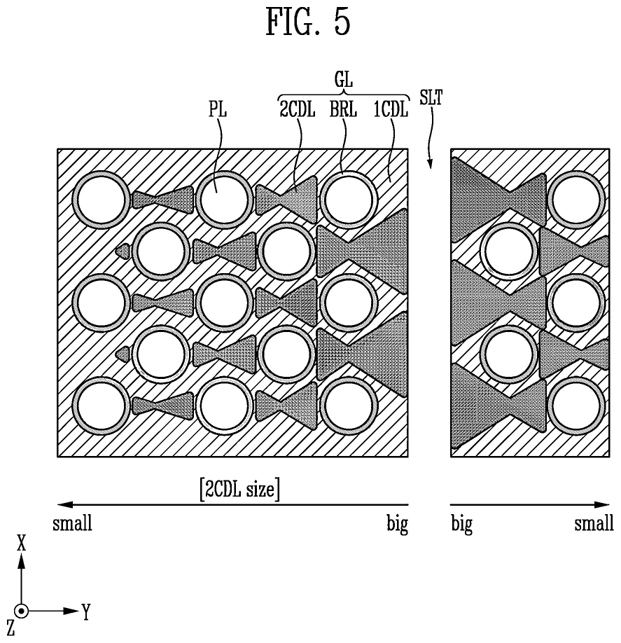

FIG. 5 is a plan view illustrating a memory device according to an embodiment of the present disclosure.

Referring to FIG. 5, the plugs PL may be formed to pass through the gate lines GL in the vertical direction (Z direction), and may be arranged in a zigzag pattern along the first and second directions (X and Y directions). The gate lines GL may include the barrier layer BRL, the first conductive layer 1CDL, and the second conductive layer 2CDL. The barrier layer BRL may be formed to have a uniform thickness along an outer wall of the plugs PL. The first conductive layer 1CDL may configure most of the gate lines GL, and the second conductive layer 2CDL may be formed in remaining areas where the barrier layer BRL and the first conductive layer 1CDL are not formed in the gate lines GL.

Because the second conductive layer 2CDL is formed by the source gas supplied through the slit SLT, the second conductive layer 2CDL may have the same size as the void formed in the gate lines GL. That is, because the void formed in a step of forming the first conductive layer 1CDL is filled with the second conductive layer 2CDL, the size of the second conductive layer 2CDL is increased as the second conductive layer 2CDL is close to the slit SLT and is decreased as the second conductive layer 2CDL is far from the slit SLT. In addition, the size of the second conductive layer 2CDL may be based on a thickness of the gate lines GL stacked apart from each other. That is, a volume of the second conductive layer 2CSL may be increased as the second conductive layer 2CSL is close to the slit SLT and may be decreased as the second conductive layer 2CSL is far from the slit SLT.

Because FIG. 5 is a diagram illustrating the size of the second conductive layer 2CDL according to a distance from the slit SLT, a shape of the second conductive layer 2CDL is not limited to a shape shown in FIG. 5, and may vary according to a shape of the void formed when the first conductive layer 1CDL is formed.

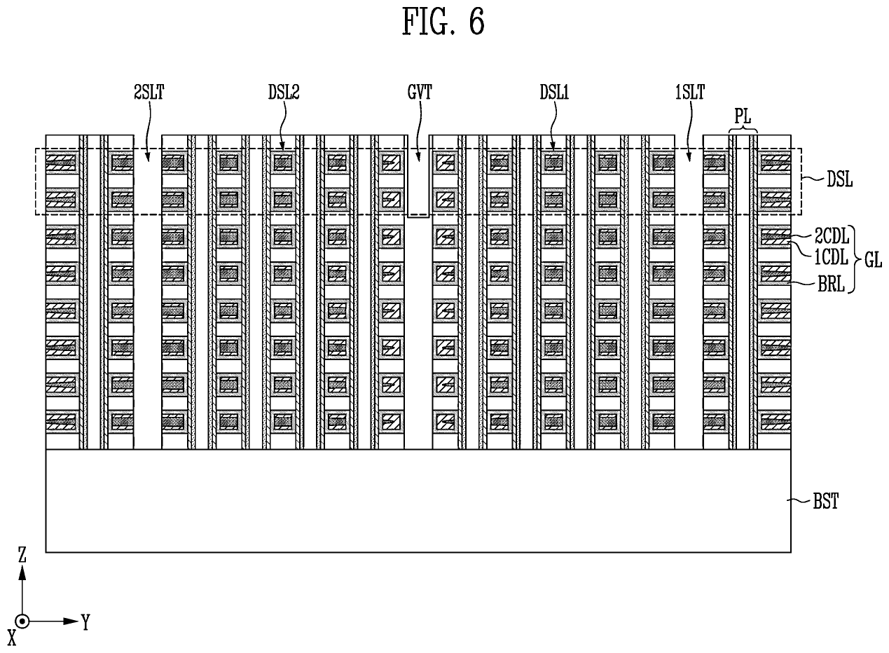

FIG. 6 is a cross-sectional view illustrating a memory device according to another embodiment of the present disclosure.

Referring to FIG. 6, as shown in FIG. 4G, after removing the barrier layer BRL, the first conductive layer 1CDL, and the second conductive layer 2CDL formed in the slit SLT, a gate separation trench GVT for separating the drain select lines DSL may be formed. For example, when first and second slits 1SLT and 2SLT are formed, the gate separation trench GVT may be formed between the first and second slits 1SLT and 2SLT. The gate separation trench GVT may be formed by etching some of the plugs PL and some of the gate lines GL. For example, the gate lines GL corresponding to the drain select line DSL may be separated from each other into first and second drain select lines DSL1 and DSL2 by the gate separation trench GVT. Because the first drain select lines DSL1 and the second drain select lines DSL2 are separated from each other by the gate separation trench GVT, different voltages may be applied to the first drain select lines DSL1 and the second drain select lines DSL2.

Also in the memory device in which the first and second slits 1SLT and 2SLT are formed, because the source gas for forming the first conductive layer 1CDL is supplied to an area between the first interlayer insulation layers 1ISL through the first and second slits 1SLT and 2SLT, the size of the void formed in the first conductive layer 1CDL may be large in an area adjacent to the first or second slit 1SLT or 2SLT, and may be decreased as the void is far from the first or second slits 1SLT or 2SLT. In other words, the size of the void formed in the first conductive layer 1CDL may be decreased from the first or second slit 1SLT or 2SLT to the gate separation trench GVT.

Therefore, the size of the second conductive layer 2CDL formed in the void may also be large in an area adjacent to the first or second slit 1SLT or 2SLT, and may be decreased as the void is far from the first and second slits 1SLT or 2SLT. In other words, the size of the second conductive layer 2CDL may be decreased from the first or second slit 1SLT or 2SLT to the gate separation trench GVT. In addition, the size of the second conductive layer 2CDL may be changed according to the thickness of the gate lines GL stacked apart from each other.

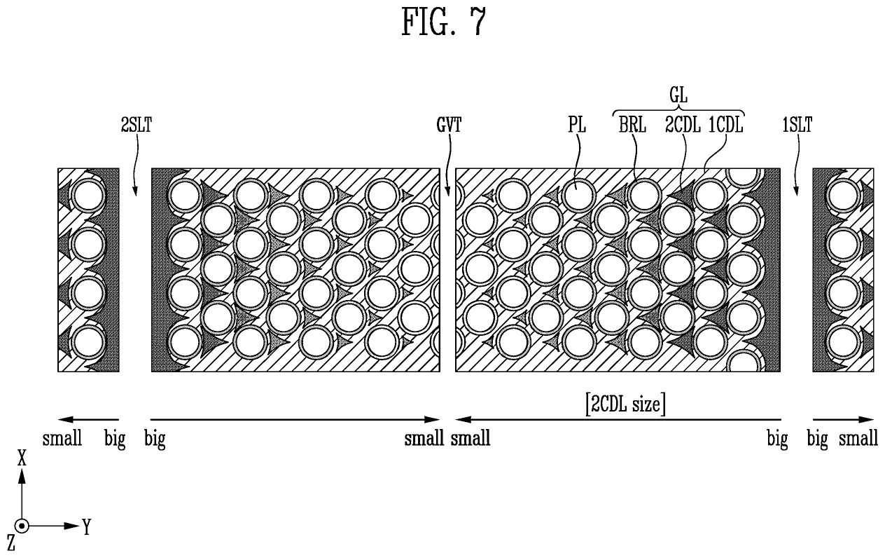

FIG. 7 is a plan view illustrating a memory device according to another embodiment of the present disclosure.

Referring to FIG. 7, the plugs PL may be formed to pass through the gate lines GL in the vertical direction (Z direction), and may be arranged in a zigzag pattern along the first and second directions (X and Y directions). The gate lines GL may include the barrier layer BRL, the first conductive layer 1CDL, and the second conductive layer 2CDL. The barrier layer BRL may be formed to have a uniform thickness along an outer wall of the plugs PL. The first conductive layer 1CDL may configure most of the gate lines GL, and the second conductive layer 2CDL may be formed in remaining areas where the barrier layer BRL and the first conductive layer 1CDL are not formed in the gate lines GL.

Because the second conductive layer 2CDL is formed by the source gas supplied through the first and second slits 1SLT and 2SLT, the second conductive layer 2CDL may have the same size as a void formed in the gate lines GL. That is, because the void formed in a step of forming the first conductive layer 1CDL is filled with the second conductive layer 2CDL, the size of the second conductive layer 2CDL is increased as the second conductive layer 2CDL is close to the first or second slit 1SLT or 2SLT, and is decreased as the second conductive layer 2CDL is close to the gate separation trench GVT.

Because FIG. 7 is a diagram illustrating the size of the second conductive layer 2CDL according to a distance between the first or second slit 1SLT or 2SLT and the gate separation trench GVT, the shape is not limited to a shape shown in FIG. 7 and may vary according to the shape of the void formed when the first conductive layer 1CDL is formed.

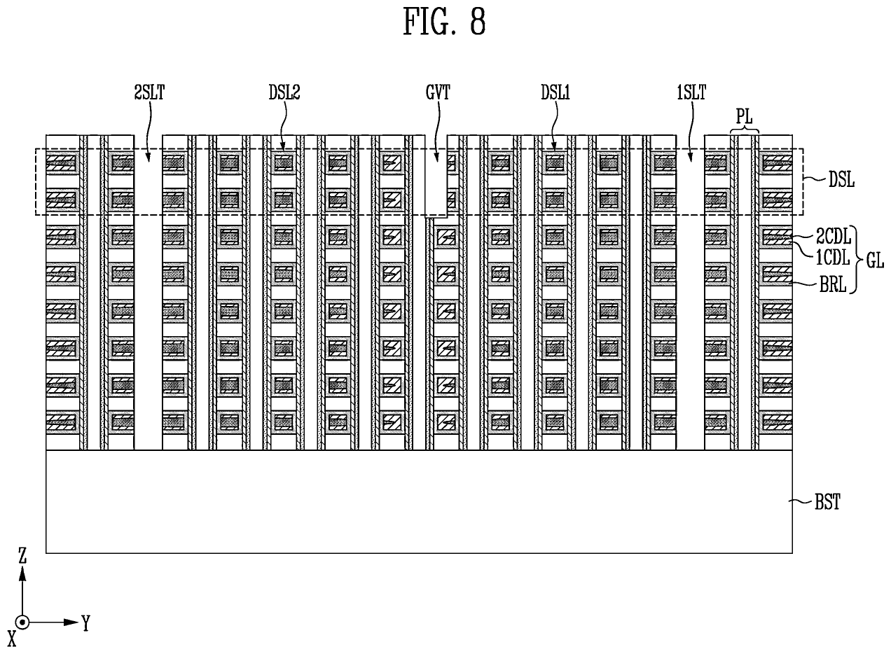

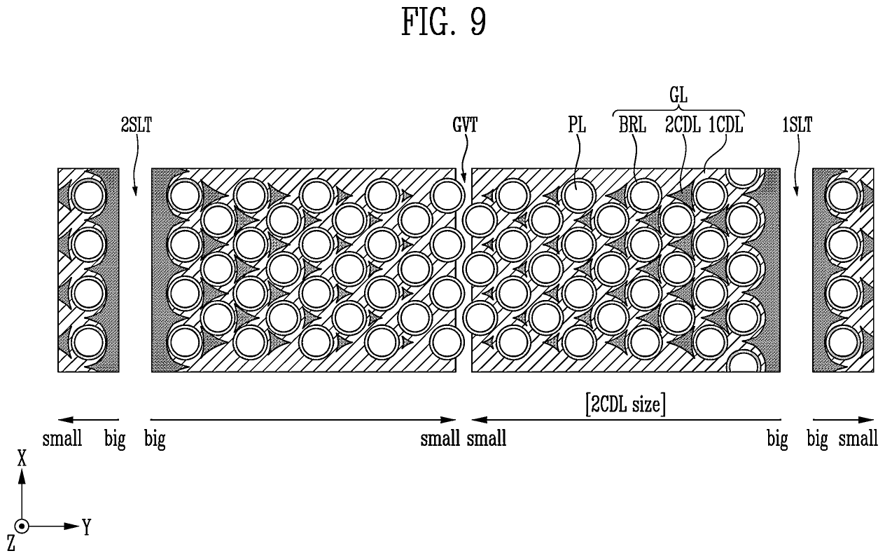

FIG. 8 is a cross-sectional view illustrating a memory device according to another embodiment of the present disclosure, and FIG. 9 is a plan view illustrating a memory device according to another embodiment of the present disclosure.

Referring to FIGS. 8 and 9, remaining configurations except for a position of the gate separation trench GVT are the same as the configurations described with reference to FIGS. 6 and 7, and thus an overlapping description is omitted.

The gate separation trench GVT may be arranged to overlap a partial area of the plugs PL. For example, the gate separation trench GVT may be formed between plugs PL facing each other in a zigzag shape. In this case, because the plugs PL arranged in the X direction are not separated by the gate separation trench GVT, the plugs PL overlapping a partial area of the gate separation trench GVT may be used identically to plugs for data storage.

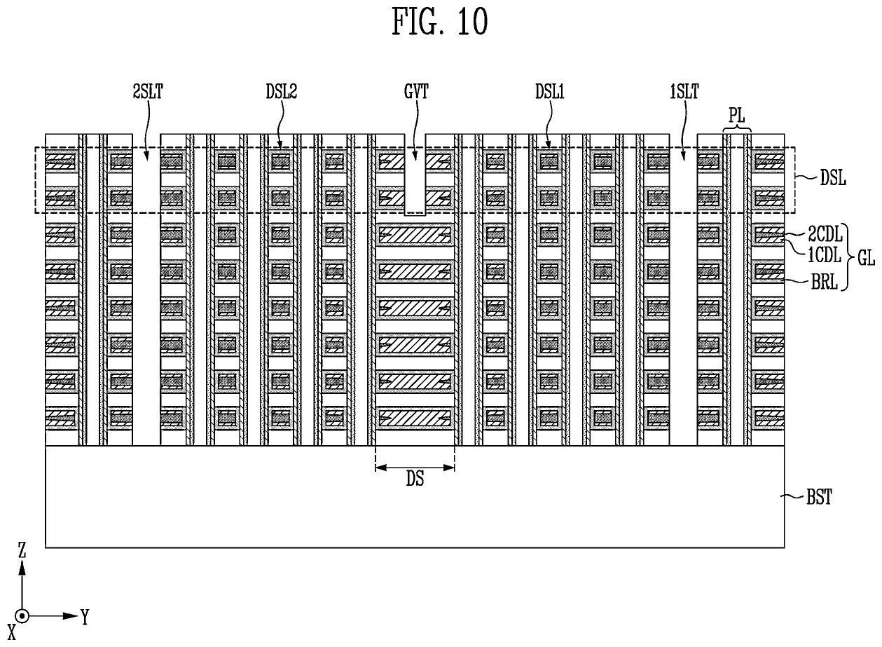

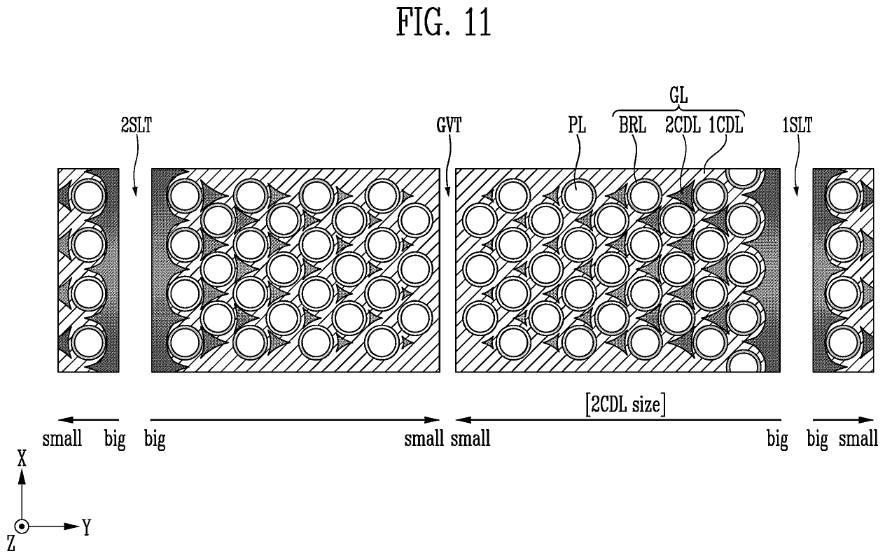

FIG. 10 is a cross-sectional view illustrating a memory device according to another embodiment of the present disclosure, and FIG. 11 is a plan view illustrating a memory device according to another embodiment of the present disclosure.

Referring to FIGS. 10 and 11, the plugs PL may not be formed in an area where the gate separation trench GVT is positioned. That is, in a step of forming the plugs PL, the plugs PL are not formed in an area where the gate separation trench GVT is to be formed. In this case, a distance DS between the plugs PL positioned at both ends of the gate separation trench GVT and facing each other may be reduced.

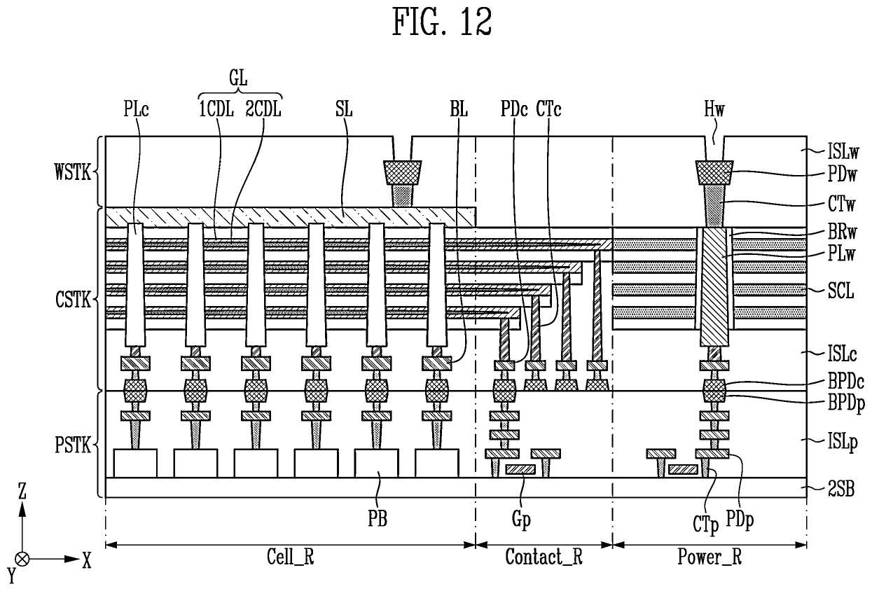

FIG. 12 is a cross-sectional view illustrating a memory device according to another embodiment of the present disclosure.

Referring to FIG. 12, the memory device may include structures PSTK, CSTK, and WSTK formed on different substrates and then stacked. For example, the memory device may include a peripheral structure PSTK including peripheral circuits, a cell structure CSTK including memory cells and stacked on the peripheral structure PSTK, and a power structure WSTK stacked on the cell structure CSTK. When the cell structure CSTK is formed on a first substrate (not shown), the peripheral structure PSTK may be formed on a second substrate 2SB. For example, after the cell structure CSTK contacts the peripheral structure PSTK, the first substrate of the cell structure CSTK may be removed. After the first substrate is removed, the power structure WSTK may be stacked on the cell structure CSTK. The peripheral structure PSTK, the cell structure CSTK, and the power structure WSTK are specifically described as follows.

The peripheral structure PSTK may include the second substrate 2SB and a peripheral circuit formed on the second substrate 2SB. The peripheral circuit may be the peripheral circuit 190 described with reference to FIG. 1. For example, the peripheral circuit may include page buffers PB, peripheral gates Gp, peripheral contacts CTp, peripheral pads PDp, and peripheral bonding pads BPDp. In addition to the page buffers PB, peripheral gates Gp, peripheral contacts CTp, peripheral pads PDp, and peripheral bonding pads BPDp shown in FIG. 11, the peripheral circuit may include the remaining circuits of the peripheral circuit 190 shown in FIG. 1. A peripheral insulating layer ISLp may be formed between the page buffers PB, the peripheral gates Gp, the peripheral contacts CTp, the peripheral pads PDp, and the peripheral bonding pads BPDp, to electrically insulate between each of circuits. Circuits that are required to be electrically connected may be connected through the peripheral contacts CTp, the peripheral pads PDp, and the peripheral bonding pads BPDp formed of a conductive material. The peripheral structure PSTK may be divided into a cell region Cell_R, a contact region Contact_R, and a power region Power_R. The page buffers PB may be positioned in the cell region Cell_R of the peripheral structure PSTK, and the peripheral gates Gp, the peripheral contacts CTp, the peripheral pads PDp, and the peripheral bonding pads BPDp may be positioned in the cell region Cell_R, the contact region Contact_R, and the power region Power_R of the peripheral structure PSTK.

The cell structure CTSK may include cell bonding pads BPDc, cell contacts CTc, cell pads PDc, bit lines BL, gate lines GL, cell plugs PLc, a source line SL, sacrificial layers SCL, a power plug PLw, a power barrier layer BRw, and cell insulating layers ISLc. The cell bonding pads BPDc may contact the peripheral bonding pads BPDp of the peripheral structure PSTK. The cell bonding pads BPDc and the peripheral bonding pads BPDp may be formed of the same material. For example, the cell bonding pads BPDc and the peripheral bonding pads BPDp may be formed of tungsten. An insulating layer positioned at the lowermost end of the cell insulating layers ISLc of the cell structure CSTK may contacts the peripheral insulating layer ISLp of the peripheral structure PSTK. The cell insulating layers ISLc and the peripheral insulating layer ISLp may be formed of a silicon oxide layer. A portion of the gate lines GL and the cell insulating layers ISLc may be stacked on each other. The gate lines GL may be stacked in a step shape. A length of the gate lines GL shown in FIG. 11 may become shorter as a distance from the peripheral structure PSTK is decreased, but a structure, a volume, and the length of the gate lines GL are not limited to a structure shown in FIG. 11. For example, the length of the gate lines GL may become longer as the distance from the peripheral structure PSTK is decreased.

Each of the gate lines GL may include the first conductive layer 1CDL and the second conductive layer 2CDL as described with reference to FIG. 3. The second conductive layer 2CDL may be formed of a material having physical properties different from those of the first conductive layer 1CDL. For example, the first conductive layer 1CDL may be formed of tungsten (W) and the second conductive layer 2CDL may be formed of molybdenum (Mo). When the first conductive layer 1CDL is formed of molybdenum (Mo), the second conductive layer 2CDL may be formed of tungsten (W). The gate lines GL may extend from the cell region Cell_R of the cell structure CSTK to the contact region Contact_R.

The cell plugs PLc and the bit lines BL may be positioned in the cell region Cell_R of the cell structure CSTK. The bit lines BL may be electrically connected to the page buffers PB through the cell contacts CTc, the cell pads PDc, the cell bonding pads BPDc, the peripheral bonding pads BPDp, the peripheral contacts CTp, and the peripheral pads PDp positioned in the cell region Cell_R. The cell plugs PLc may pass through the gate lines GL and the cell insulating layers ISLc. A lower portion of the cell plugs PLc may be electrically connected to the bit lines BL through the cell contacts CTc, and an upper portion of the cell plugs PLc may be electrically connected to the source line SL.

A portion of the cell contacts CTc may contact the gate lines GL in the contact region Contact_R of the cell structure CSTK. The gate lines GL may be electrically connected to a peripheral circuit through the cell contacts CTc, the cell pads PDp, the cell bonding pads BPDc, the peripheral bonding pads BPDp, the peripheral contacts CTp, and the peripheral pads PDp positioned in the contact region Contact_R.

In the power region Power_R of the cell structure CSTK, the sacrificial layers SCL and the cell insulating layers ISLc may be alternately stacked. The sacrificial layers SCL may be formed of a silicon nitride layer. The power plug PLw may pass through the sacrificial layers SCL and the cell insulating layers ISLc. The power barrier layer BRw may surround a side surface of the power plug PLw.

The power structure WSTK may include a power insulating layer ISLw, power contacts CTw, and power pads PDw. The power contacts CTw may contact the source line SL and the power plug PLw. The power pads PDw may be positioned on the power contacts CTw and may be exposed through power supply holes Hw of the power insulating layer ISLw. A power voltage or a ground voltage may be supplied through the power supply holes Hw.

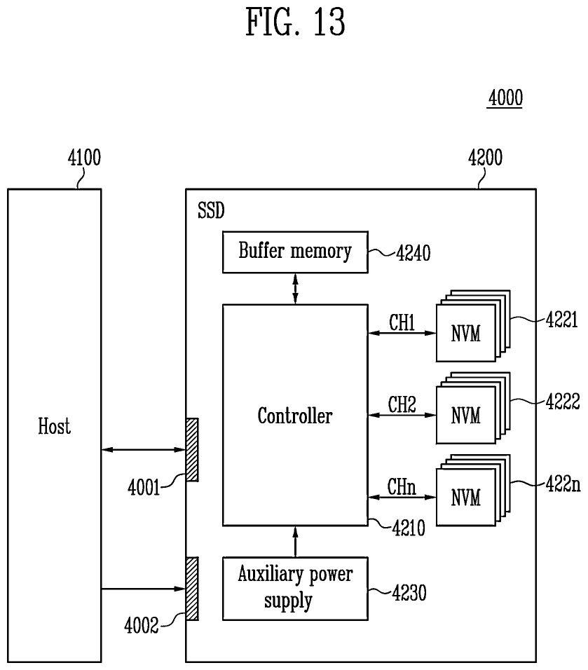

FIG. 13 is a diagram illustrating a solid state drive (SSD) system to which a memory device in accordance with the present disclosure is applied.

Referring to FIG. 13, the SSD system 4000 includes a host 4100 and an SSD 4200. The SSD 4200 may exchange a signal with the host 4100 through a signal connector 4001 and receive power through a power connector 4002. The SSD 4200 includes a controller 4210, a plurality of flash memories 4221 to 422n, an auxiliary power supply 4230, and a buffer memory 4240.

According to an embodiment of the present disclosure, each of the plurality of flash memories 4221 to 422n may be configured identically to the memory device 100 described with reference to FIG. 1.

The controller 4210 may control the plurality of flash memories 4221 to 422n in response to the signal received from the host 4100. For example, the signal may be based on an interface between the host 4100 and the SSD 4200. For example, the signal may be defined by at least one of multiple interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power supply 4230 may be connected to the host 4100 through the power connector 4002. The auxiliary power supply 4230 may receive a power voltage from the host 4100 and be charged by the power voltage. The auxiliary power supply 4230 may provide the power voltage to the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 may be used as a buffer memory of the SSD 4200. For example, the buffer memory 4240 may temporarily store data received from the host 4100 or data received from the plurality of flash memories 4221 to 422n, or may temporarily store metadata (for example, a mapping table) of the flash memories 4221 to 422n. The buffer memory 4240 may include volatile memory such as DRAM, SDRAM, DDR SDRAM, and LPDDR SDRAM, or nonvolatile memory such as FRAM, ReRAM, STT-MRAM, and PRAM.

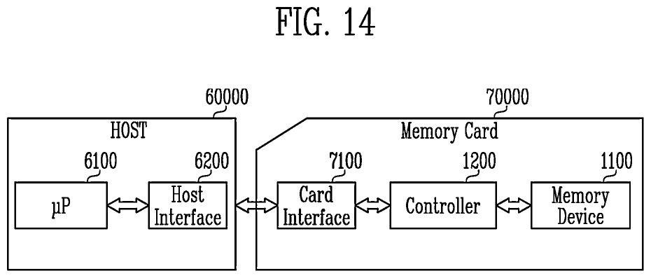

FIG. 14 is a diagram illustrating a memory card system to which a memory device in accordance with the present disclosure is applied.

Referring to FIG. 14, the memory system 70000 may be implemented as a memory card or a smart card. The memory system 70000 may include a memory device 1100, a controller 1200, and a card interface 7100.

The memory device 1100 may be configured identically to the memory device 100 shown in FIG. 1.

The controller 1200 may control data exchange between the memory device 1100 and the card interface 7100. According to an embodiment, the card interface 7100 may be a secure digital (SD) card interface or a multi-media card (MMC) interface, but is not limited thereto.

The card interface 7100 may interface data exchange between a host 60000 and the controller 1200 according to a protocol of the host 60000. According to an embodiment, the card interface 7100 may support a universal serial bus (USB) protocol, and an inter chip (IC)-USB protocol. Here, the card interface 7100 may refer to hardware capable of supporting a protocol that is used by the host 60000, software installed in the hardware, or a signal transmission method.

When the memory system 70000 is connected to a host interface 6200 of the host 60000 such as a PC, a tablet PC, a digital camera, a digital audio player, a mobile phone, a console video game hardware, or a digital set-top box, the host interface 6200 may perform data communication with the memory device 1100 through the card interface 7100 and the controller 1200 under the control of a microprocessor (μP) 6100.

What is claimed is:

1. A memory device comprising:
interlayer insulation layers spaced apart from each other and stacked;
gate lines formed between the interlayer insulation layers; and
a plug vertically passing through the interlayer insulation layers and the gate lines,
wherein each of the gate lines comprises:
a barrier layer formed along an inner wall of the interlayer insulation layer and the plug;
a first conductive layer surrounded by the barrier layer; and
a second conductive layer surrounded by the first conductive layer and having a grain size different from a grain size of the first conductive layer,
wherein a volume of the second conductive layer is variable along a direction in which the gate lines extend.

2. The memory device of claim 1, wherein the barrier layer comprises titanium nitride (TiN).

3. The memory device of claim 1, wherein the first conductive layer and the second conductive layer are formed of materials having different melting points.

4. The memory device of claim 3, wherein the material of the second conductive layer has a melting point lower than the material of the first conductive layer.

5. The memory device of claim 3, wherein the first conductive layer is formed of a material having a melting point lower than a melting point of a material of the second conductive layer.

6. The memory device of claim 1, wherein the grain size of the second conductive layer is less than the grain size of the first conductive layer.

7. The memory device of claim 1, wherein the grain size of the first conductive layer is less than the grain size of the second conductive layer.

8. The memory device of claim 1, wherein the first conductive layer is formed of tungsten (W), and the second conductive layer is formed of molybdenum (Mo).

9. The memory device of claim 1, wherein the first conductive layer is formed of molybdenum (Mo), and the second conductive layer is formed of tungsten (W).

10. The memory device of claim 1, wherein a portion of the plug protrudes above the interlayer insulation layers and the gate lines.

11. The memory device of claim 10, further comprising:
a source line contacting the protruding plug.

12. The memory device of claim 11, wherein the plug comprises:
a blocking layer vertically passing through the interlayer insulation layers and the gate lines;
a charge trap layer formed along an inner wall of the blocking layer;
a tunnel insulation layer formed along an inner wall of the charge trap layer;
a channel layer formed along an inner wall of the tunnel insulation layer; and
a core insulation layer filling a space surrounded by the channel layer.

13. The memory device of claim 12, wherein the channel layer of the plug contacts the source line.

14. A memory device comprising:
interlayer insulation layers and gate lines alternately stacked on each other between bit lines and source lines;
plugs vertically passing through the interlayer insulation layers and the gate lines; and
a first slit vertically passing through the interlayer insulation layers and the gate lines to separate the interlayer insulation layers and the gate lines into different memory blocks,
wherein each of the gate lines includes:
a barrier layer;
a first conductive layer surrounded by the barrier layer; and
a second conductive layer surrounded by the first conductive layer and having a grain size different from a grain size of the first conductive layer, wherein a size of the second conductive layer increases with decreasing distance of the second conductive layer from the first slit.

15. The memory device of claim 14, wherein the grain size of the second conductive layer is less than the grain size of the first conductive layer.

16. The memory device of claim 14, wherein the grain size of the first conductive layer is less than the grain size of the second conductive layer.

17. The memory device of claim 14, wherein the first conductive layer is formed of tungsten (W), and the second conductive layer is formed of molybdenum (Mo).

18. The memory device of claim 14, wherein the first conductive layer is formed of molybdenum (Mo), and the second conductive layer is formed of tungsten (W).

19. The memory device of claim 14, wherein a volume of the second conductive layer is changed according to a distance from the first slit.

20. The memory device of claim 14, further comprising:
a gate separation trench separating each of some gate lines adjacent to the bit lines among the gate lines.

21. The memory device of claim 20, wherein the gate separation trench is extended along a direction perpendicular to a direction in which the bit lines extend.

22. The memory device of claim 15, wherein a volume of the second conductive layer decreases with decreasing distance to the gate separation trench.

23. The memory device of claim 14, further comprising:
a second slit spaced apart from the first slit.

24. The memory device of claim 23, wherein a volume of the second conductive layer increases with decreasing distance to the first slit or the second slit, and decreases with decreasing distance to a center between the first and second slits.

25. A method of manufacturing a memory device, the method comprising:
alternately stacking interlayer insulation layers and sacrificial layers;
forming plugs vertically passing through the interlayer insulation layers and the sacrificial layers;
forming a slit vertically passing through the interlayer insulation layers and the sacrificial layers in a boundary area between different memory blocks;
removing the sacrificial layers exposed through a sidewall of the slit;
forming a first conductive layer in an area from which the sacrificial layers are removed; and
filling a void generated when the first conductive layer is formed with a second conductive layer having a first grain size different from a grain size of the first conductive layer.

26. The method of claim 25, wherein the grain size of the first conductive layer is less than the grain size of the second conductive layer.

27. The method of claim 26, wherein the first conductive layer is formed of tungsten (W), and the second conductive layer is formed of molybdenum (Mo).

28. The method of claim 25, wherein the grain size of the first conductive layer is greater than the grain size of the second conductive layer.

29. The method of claim 28, wherein the first conductive layer is formed of molybdenum (Mo), and the second conductive layer is formed of tungsten (W).

30. The method of claim 25, further comprising:
performing a heat treatment process, after filling the void generated when the first conductive layer is formed with the second conductive layer.
